(19) United States
(12) Patent Application Publication
(10) Pub. No.: US 2025/0241033 A1
(43) Pub. Date: Jul. 24, 2025

(54) PIEZOELECTRIC DEVICES INCLUDING COMPOUND SEMICONDUCTOR MATERIALS AND A SUPERLATTICE LAYER

(71) Applicant: ATOMERA INCORPORATED, LOS GATOS, CA (US)

(72) Inventors: JERRY WAYNE JOHNSON, HAMPSTEAD, NC (US); MAREK HYTHA, BROOKLINE, MA (US); ROBERT J. MEARS, WELLESLEY, MA (US); NYLES WYNN CODY, TEMPE, AZ (US)

(21) Appl. No.: 19/028,119

(22) Filed: Jan. 17, 2025

Related U.S. Application Data
(60) Provisional application No. 63/622,133, filed on Jan. 18, 2024.
(60) Provisional application No. 63/626,703, filed on Jan. 30, 2024.
(60) Provisional application No. 63/631,149, filed on Apr. 8, 2024.

(51) Int. Cl. H10D 62/815; H10D 62/00; H10N 30/074; H10N 30/85

(52) U.S. Cl. CPC H10D 62/8162; H10N 30/85; H10D 62/01; H10N 30/074

(57) ABSTRACT

A semiconductor device may include a semiconductor substrate and a superlattice layer on the semiconductor substrate. The superlattice layer may include a plurality of stacked groups of layers, with each group of layers including a plurality of stacked base semiconductor monolayers defining a base semiconductor portion, and at least one non-semiconductor monolayer constrained within a crystal lattice of adjacent base semiconductor portions. The semiconductor device may also include a piezoelectric layer on the superlattice layer and comprising a Group III-N semiconductor.

### CROSS-REFERENCE TO RELATED APPLICATIONS

This application claims the benefit of U.S. provisional app. Nos. 63/631,149 filed Apr. 8, 2024; 63/626,703 filed Jan. 30, 2024; and 63/622,133 filed Jan. 18, 2024, all of which are hereby incorporated herein in their entireties by reference.

### TECHNICAL FIELD

The present disclosure generally relates to semiconductor devices and, more particularly, to semiconductor devices with enhanced semiconductor materials and associated methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region includes alternate layers of SiO2/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A semiconductor device may include a semiconductor substrate and a superlattice layer on the semiconductor substrate. The superlattice layer may include a plurality of stacked groups of layers, with each group of layers including a plurality of stacked base semiconductor monolayers defining a base semiconductor portion, and at least one non-semiconductor monolayer constrained within a crystal lattice of adjacent base semiconductor portions. The semiconductor device may also include a piezoelectric layer on the superlattice layer and comprising a Group III-N semiconductor.

The semiconductor device may further include at least one electrode adjacent the piezoelectric layer. In one example implementation, the at least one electrode may be configured to induce an acoustic wave along a surface of the piezoelectric layer to define a surface acoustic wave (SAW) filter. In another example implementation, the at least one electrode may be configured to induce an acoustic wave within the piezoelectric layer to define a bulk acoustic wave (BAW) filter.

By way of example, the Group III-N semiconductor may comprise AlN, ScN, or their alloys, and the semiconductor substrate may comprise a single crystal silicon substrate having a (111) orientation with an off-cut of 0.5° or less. Also by way of example, the base semiconductor monolayers may comprise silicon, and the at least one non-semiconductor monolayer may comprise oxygen and/or carbon.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4 is a schematic cross sectional diagram of a semiconductor device including a Group III-N semiconductor stack with a superlattice layer providing advantages in an example embodiment.

FIG. 5 is a schematic cross sectional diagram of another semiconductor device including a Group III-N semiconductor stack with a superlattice layer providing enhanced stress/strain control in an example embodiment.

FIG. 6 is a schematic cross sectional diagram of the Group III-N semiconductor stack of FIG. 4 separated from the Si (111) substrate at the superlattice layer for coupling to a second substrate in accordance with an example embodiment.

FIG. 7 is a flow diagram illustrating a method of making the embodiments of FIGS. 4-6.

FIGS. 8 and 9 are schematic cross sectional diagrams of example piezoelectric devices including a Group III-N piezoelectric layer on a superlattice layer.

FIG. 10 is a flow diagram illustrating an example method for making the piezoelectric devices of FIGS. 8 and 9.

FIG. 11 is a schematic cross sectional diagram of a semiconductor device including both Group III-N and Si circuit regions above a superlattice in accordance with an example embodiment.

FIG. 12 is a flow diagram illustrating a method for making the semiconductor device of FIG. 11 in an example embodiment.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers, and that this accordingly leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO₂. Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si—SiO₂ interface, reducing the presence of sub-stoichiometric SiOₓ. Alternately, the trapping of interstitials by MST layers may reduce the concentration of interstitial silicon proximate to the Si—SiO₂ interface, reducing the tendency to form sub-stoichiometric SiOₓ. Sub-stoichiometric SiOₓ at the Si—SiO₂ interface is known to exhibit inferior insulating properties relative to stoichiometric SiO₂. Reducing the amount of sub-stoichiometric SiOₓ at the interface more effectively confines free carriers (electrons or holes) in the silicon, and thus improves the mobility of these carriers due to electric fields applied parallel to the interface, as is standard practice in field effect transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as discussed further in U.S. Pat. Nos. 7,517,702, which is also from the present Applicant and is hereby incorporated herein in its entirety by reference.

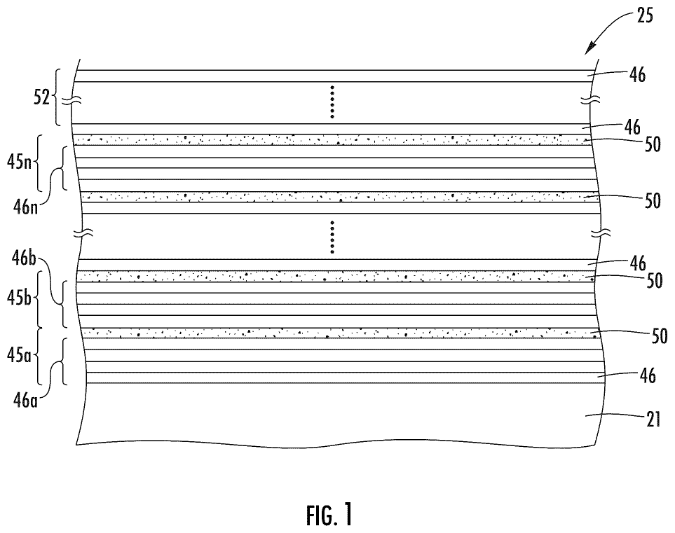

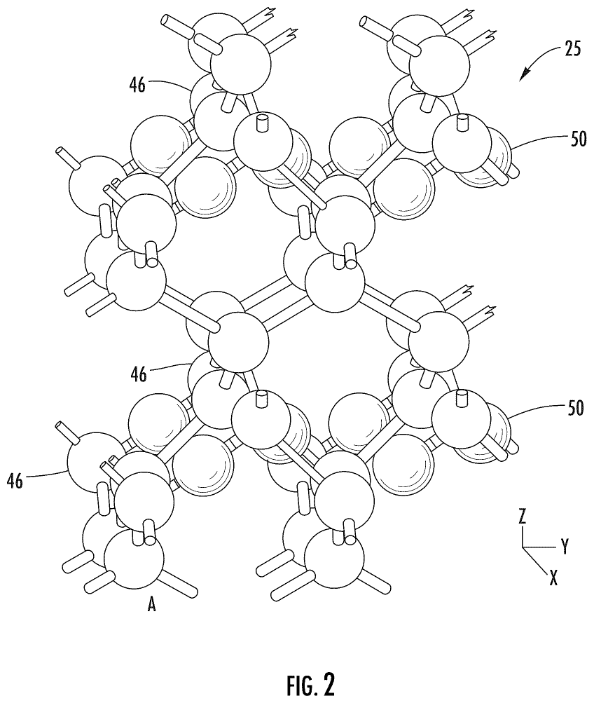

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Moreover, this superlattice structure may also advantageously act as a barrier to dopant and/or material diffusion between layers vertically above and below the superlattice 25. These properties may thus advantageously allow the superlattice 25 in one example implementation to provide an interface for high-K dielectrics which not only reduces diffusion of the high-K material into the channel region, but which may also advantageously reduce unwanted scattering effects and improve device mobility, as will be appreciated by those skilled in the art.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed, it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the invention may be readily adopted and implemented, as will be appreciated by those skilled in the art.

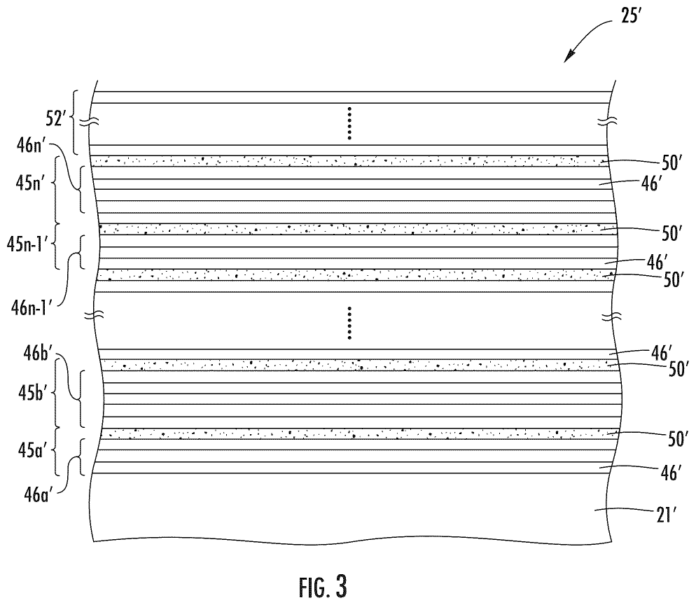

Referring now additionally to FIG. 3, another embodiment of a superlattice 25′ in accordance with the invention having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

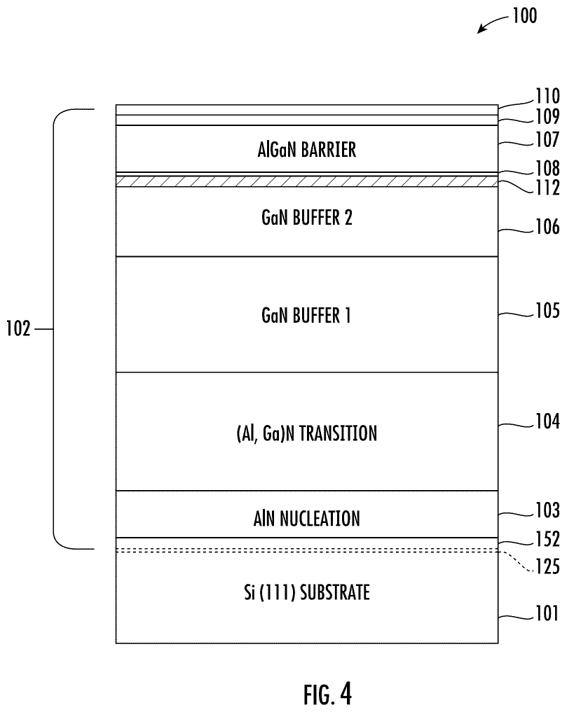

Turning now to FIGS. 4-6, example embodiments are provided in which one or more of the above-described MST films are incorporated into Group III-N semiconductor (e.g., GaN and AlN) devices to provide fabrication and/or performance benefits over conventional Group III-N devices. By way of background, various approaches are used for fabricating Group III-N structures on silicon substrates, such as for high power, high frequency, and high temperature applications. For example, these structures may be used for RF transistors, power transistors, piezoelectric sensors, and optoelectronic devices (e.g., LEDs, micro-LEDs, lasers, optical detectors, etc.), as will be discussed further below. However, such approaches may suffer from excessive stress and/or bowing resulting from the differences in materials.

The semiconductor device 100 shown in FIG. 4 illustratively includes an MST film 125 on a substrate 101 to provide mechanical compliance for stress management. More particularly, in the illustrated example the MST film 125 is leveraged more to provide a mechanical interface between the Si (111) substrate and overlying stack 102 of Group III-N layers, as opposed to the enhanced electrical behaviors of MST films described above. More particularly, Applicant theorizes without wishing to be bound thereto that the MST film 125 interface will advantageously provide less stress in overlying nitride films, resulting in less curvature (warping/bowing) of the wafer, which in turn advantageously allows for the growth of thicker GaN layers.

Above the AlN nucleation layer 103 is a transition layer 104. Most commonly, such transition layers are either graded AlGaN layers as shown, or superlattices of alternating semiconductor materials may also be used. Above the transition layer 104 is a first GaN buffer layer 105, which is typically doped with C or Fe to improve breakdown, for example.

The nucleation layer 103, transition layer 104, and first GaN buffer layer 105 are important for stress management. In the case of electronic devices such as transistors, the thicknesses of transition layer 104 and first GaN buffer layer 105 are often voltage-dependent (higher voltage=thicker epi=more difficult). By way of example, for RF and microwave applications (e.g., at operating voltage <200V and operating frequency >100 MHz), their combined thickness may be on the order of ˜1.5 um, and for power electronics applications (e.g., at operating frequency <10 MHz) they may be on the order of ˜4-6 um.

A second GaN buffer layer 106 is above the first GaN buffer layer 105, and it is typically undoped to promote desired 2-dimensional electron gas (2DEG) transport properties. Above the second GaN buffer layer 106 is a barrier layer 107 (here AlGaN), which is the primary driver of on-state characteristics (drain current, pinchoff voltage, etc.). In the illustrated configuration, an AlN spacer 108, GaN cap 109, and SiNₓ cap are also provided, although these layers are optional. The AlN spacer 108 may be included to help enhance transport properties. The GaN cap 109 may help reduce leakage current and/or tailor surface properties, and the SiNₓ cap 110 may help to passivate the surface.

Also shown in the illustrated example is a 2DEG layer 112, which is a sheet of electrons located below the AlN spacer 108 or AlGaN barrier 107 interface with the second GaN buffer layer 106. Note that the 2DEG layer 112 is not grown like the other layers in the stack 102, but rather is the result of the layer design. The 2DEG layer 112 carries current during device operation.

For the illustrated embodiment, the MST layer 125 is grown on the Si (111) substrate 101, followed by a cap layer 152 growth. Generally speaking, the cap layer 152 will be relatively small so that the MST film 125 is close to the overlying layer (here the AlN nucleation layer 103) to provide the most stress relief. By way of example, the cap layer 152 may have a thickness in a range of 3-5 nm, although other thicknesses may be used in different embodiments. In addition to the lattice mismatch between Si (111) and AlN, there is also a lattice mismatch between AlN and GaN, with AlN having a slightly smaller lattice. The MST film 125 may advantageously alleviate stress from both of these mismatches.

Different variations of MST films 125 may also be used, such as with oxygen (MST-O) or carbon (MST-C) as the non-semiconductor material (or a combination of both in some instances). Other variations may include the number of layers/thickness, layer configurations (e.g., 3/1/5/1, 4/1, etc.), as well as the depth of the MST layer 125 in the substrate, which is determined by the thickness of the cap layer 152.

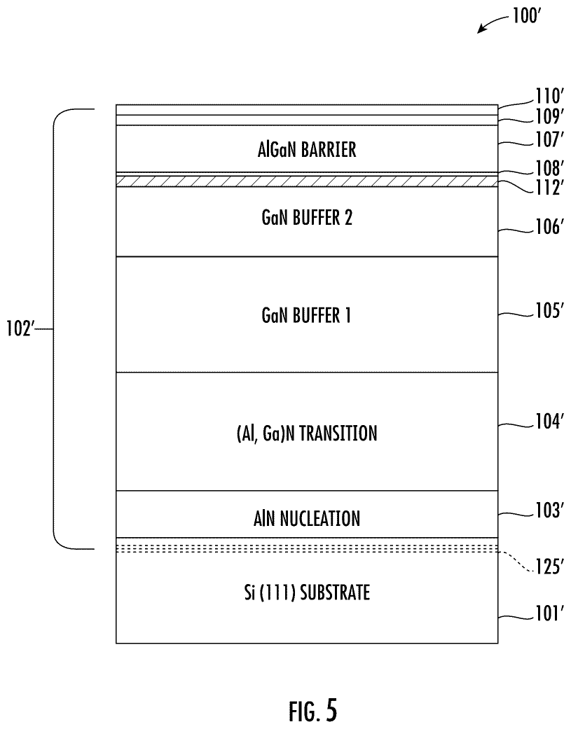

In this regard, another example semiconductor device 100′ is provided in FIG. 5 in which an MST-C layer 125′ is positioned directly adjacent the AlN nucleation layer 103′ at the top of the substrate 101′. That is, this configuration incorporates an MST-C film 125′ (e.g., an MST film including silicon monolayers 46 and carbon non-semiconductor monolayers 50) designed to place a significant amount of C in the Si substrate 101′, and more particularly very close to the surface (and potentially without a cap layer). Applicant theorizes, without wishing to be bound thereto, that this may advantageously convert the substrate 101′ surface into an “SiC-like” substrate, meaning it provides the benefits of SiC (a wide-bandgap semiconductor material which is a better lattice match to GaN than Si) without the prohibitive cost associated with fabricating a full SiC substrate. Through the MST-C film 125′ exhibiting properties similar to those of SiC, this may also enhance thermal conductivity in addition to providing the improved lattice matching, as will be appreciated by those skilled in the art.

For this application, the MST-C film 125′ may be grown using a layered approach similar to those discussed above, and different temperature anneals may be used to provide different SiC “signatures”. That is, the MST-C film 125′ is not bulk SiC, but Applicant theorizes that it will exhibit bulk SiC characteristics sufficient enough to achieve the above-noted benefits of improved lattice matching and thermal conductivity relative to a silicon substrate.

This approach may be particularly advantageous in that it overcomes difficulties with prior attempts to grow epitaxial SiC on silicon, such as nucleation, registry, etc. Notwithstanding the reduced mismatch in the way the growth/defect structure may evolve when GaN is grown above the MST-C film 125′, an AlN nucleation layer 103′ may still be used (though it may also potentially be omitted in some configurations). Further details on incorporating carbon monolayers within an MST film are set forth in U.S. Pat. No. 11,837,634 to Weeks et al., which is assigned to the present Applicant and hereby incorporated herein in its entirety by reference.

In some implementations, the devices 100 (or 100′) may be utilized for RF applications in which the MST film 100 is used to reduce parasitic channel effects. By way of background, upon nucleating growth of GaN on a silicon substrate, diffusion of group III materials into the substrate occurs. This forms a P-type region in the substrate 101, which results in the parasitic channel. Because of the ability of the MST film 125 to impact dopant diffusion profiles, and to help terminate diffusion tails into Si, locating the MST film 125 relatively close to the surface of the substrate 101 may similarly inhibit dopant diffusion into the substrate below the MST film. In the case of RF devices, this may advantageously provide improved power and efficiency and reduce microwave loss, for example.

Prior approaches to inhibit such diffusion involve decreasing processing temperatures. However, this may cause other problems, particularly in terms of stress management. Yet, the present approach incorporating the MST film 125 as shown may allow the parasitic channel to be curtailed, while also allowing fabrication at the higher desired temperatures for enhanced stress management. Furthermore, the MST film 125 may also allow for the localization of a countercharge (dopant) in some embodiments to counteract any potential dopant that might otherwise creep down from above, as will be appreciated by those skilled in the art.

In some embodiments, an MST film 125 incorporating nitrogen may be used to provide beneficial effects with respect to the AlN nucleation layer 103. More particularly, Applicant theorizes without wishing to be bound thereto that an MST film 125 including nitrogen may reduce the level of complexity by using the same material (N) as in the nucleation layer 103 on top (AlN). Moreover, in some configurations, a SiN barrier between the substrate and nucleation layer 103 may be helpful to reduce Al migration as well.

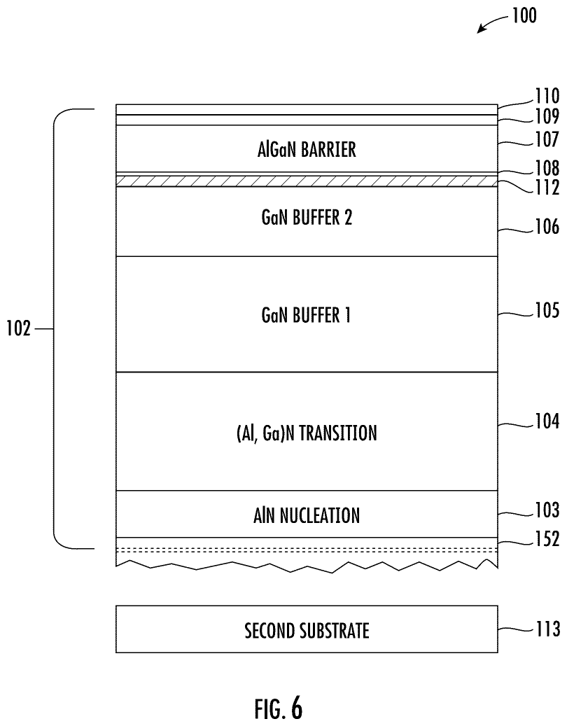

Turning now to FIG. 6, in some embodiments the MST film 125 may be used as a self-separation layer to advantageously enable lifting off of the Group III-N epitaxial stack 102. More particularly, if the MST film 125 is near the surface of the Si substrate 101, the MST film may be used be used as a separation layer (by definition, a layer of reduced mechanical strength) to cleave or remove layers above the MST film from the underlying substrate 101. This may be done mechanically, as will be appreciated by those skilled in the art. This approach provides a technical advantage in that if little or no cap layer 152 is used then everything above the MST separation layer 125 is Group III-N, and may be relatively easily bonded to a second substrate 113 such as a heat sink (e.g., for power devices), a sapphire substrate (e.g., for optical devices), or in some cases may be used with both ends exposed (e.g., for front side and backside transmission).

To function as a separation layer, in some embodiments the MST film 125 may have a higher concentration of non-semiconductor atoms than would otherwise be used for enhanced conductivity applications, for example. In other words, in the case of an MST-O layer 125 (Si/O), the MST layer may more closely approximate an oxide layer and exhibit less bulk silicon characteristics, as will be appreciated by those skilled in the art. Oxygen-based MST films allow for segregation of H adjacent the oxygen, which may be used to help weaken the bonds and reduce the strength. Thus, in some implementations H may be introduced into the stack to decrease the strength of the MST layer 125 to make it a separation layer.

For applications such as micro LEDs, the “lifted” Group III-N stack may be bonded to a pre-patterned completed CMOS digital wafer, and interconnection may be made through to the group III materials to create an LED display, as will be appreciated by those skilled in the art. Example nitrides which may be used above the separation layer for different applications may include AlN, GaN, InN, ScN, etc., and their alloys.

It should be noted that the MST layer 125 may be used with a variety of different (111) wafer configurations, including both on-axis and off-axis wafers. For many applications, silicon (111) wafers have an off cut of about 4°, whereas typical GaN device implementations utilize an on-axis (no off cut, 0°) silicon (111) wafer. Applicant theorizes without wishing to be bound thereto that the MST film may advantageously provide stress alleviation across a relatively wide range of wafers including on-axis (111) wafers and the 4° off-axis (111) wafers. In some embodiments, to minimize lattice mismatch between the Si (111) and AlN, it may be desirable to use an on-axis (111) wafer, or an off-axis wafer with an off cut of about 0.5° or less, for example. Also by way of example, the MST film 125 thickness may be up to about 100 nm, and more particularly in a range of about 20 nm to 100 nm.

The illustrated structure 100 is for an electronic device, but it will be appreciated by those skilled in the art that many other embodiments incorporating different configurations of Group IIIA/B materials on top to make different types of circuits are also possible and included within the scope of the present disclosure. With these various device configurations, incorporation of the MST film 125 interface may advantageously provide for less end wafer warp compared to conventional devices without this interface. In addition to producing a mechanically compliant layer that improves ability to control stress/strain in GaN epi, the MST layer 125 may also provide for other technical advantages including: the ability to use SEMI standard substrates instead of thicker silicon; the ability to grow a thinner epi stack (improved reactor throughput); and improved Group III-N crystal quality.

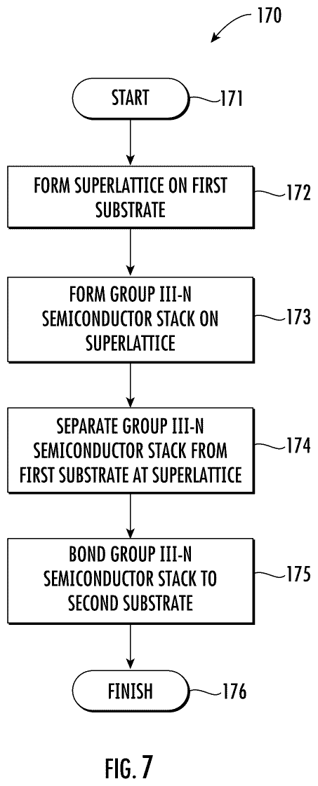

Referring additionally to the flow diagram 170 of FIG. 7, a method for making the above-described structures begins at Block 171. The superlattice 125 (or 125′ in the case of the device 100′) is formed on the substrate 101, at Block 172. The Group III-N stack 102 may then be formed on the superlattice 125/cap layer 152, at Block 173. As noted above, in some implementations the GaN stack 102 may optionally be separated from the substrate 101, at Block 174, and bonded to the second substrate 113 (Block 175), or used with both ends exposed. The method of FIG. 7 illustratively concludes at Block 176.

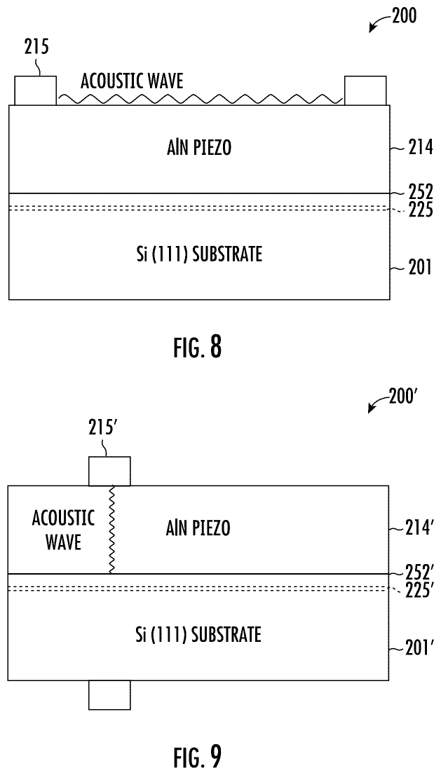

Turning now to FIGS. 8-9, example embodiments are provided in which MST films 225, 225′ are advantageously integrated in piezoelectric devices or filters 200, 200′. The illustrated devices incorporate MST films 225, 225′ at a relatively shallow depth in the substrate 201, 201′ (e.g., an Si (111) substrate) to provide stress management as described above. Here again, the depth of the cap layer 252, 252′ may vary as needed, and in some cases may be omitted. In the same manner described above, the MST films 225, 225′ advantageously enable a high quality (i.e., with less defects) piezoelectric layer 214, 214′ to be grown on the substrate 201, 201′. In the illustrated examples, the piezoelectric layers 214, 214′ are crystalline AlN filter materials, although various piezoelectric materials (including AlN, ScN, or their alloys) may also be used in different embodiments.

Moreover, the piezoelectric filters 200, 200′ further include electrodes 215, 215′ on the piezoelectric layers 214, 214′, the former being configured to induce an acoustic wave along a surface of the piezoelectric layer to define a surface acoustic wave (SAW) filter (FIG. 8), and the latter being configured to induce an acoustic wave within the piezoelectric layer to define a bulk acoustic wavce (BAW) filter (FIG. 9). Moreover, the MST layers 225, 225′ may also provide for reduced wafer curvature post-growth (warp and/or bow), as discussed further above.

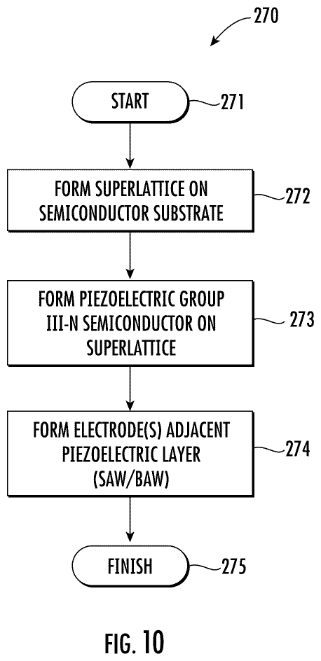

Referring additionally to the flow diagram 270 of FIG. 10, beginning at Block 271, a method of fabricating the piezoelectric devices 200, 200′ illustratively includes forming the superlattice layer 225, 225′ (and optional cap layer 252, 252′) on the substrate 201, 201′, at Block 272, followed by formation of the piezoelectric layer 214, 214′ (Block 273) an/above the superlattice. By way of example, crystalline AlN or other suitable piezoelectric materials may be used. Furthermore, the electrodes 215, 215′ are formed in the appropriate configuration for the particular device (e.g., SAW or BAW), at Block 274. The method of FIG. 10 illustratively concludes at Block 275.

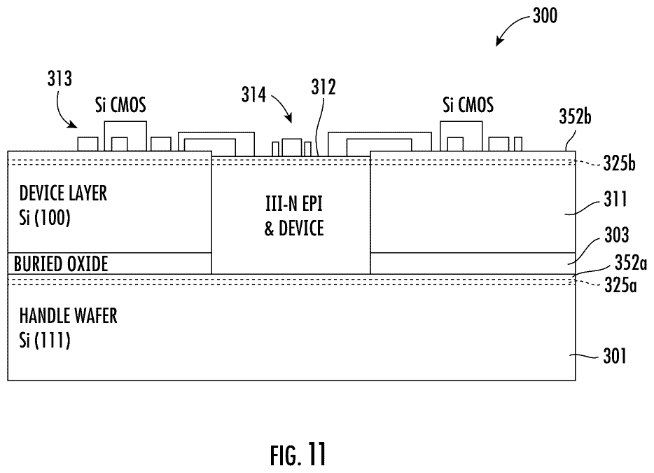

Turning now to FIG. 11, an example embodiment is provided in which MST films are advantageously integrated in a CMOS/Group III-N hybrid device 300. By way of background, there have been attempts to implement GaN devices directly alongside Si logic. However, such approaches are typically unable to provide integration at scale on a wafer. Part of the difficulty is that CMOS device fabrication requires Si with (100) orientation. However, as discussed above, this is not desirable for the formation of Group III-N materials. Instead, a first MST layer 325a (and optional cap layer 352a) is formed on an Si (111) handle wafer 301. A Si (100) active device layer 311 and buried oxide (BOX) layer 303 are positioned above the MST film 325a and cap layer 352a above the handle wafer 301 for the formation of Si CMOS circuit devices 313. Yet, between the CMOS device regions, the Si (100) may be etched down to the Si (111) handle wafer 301. In this window (trench), a group III-N device layer 312 may be epitaxially grown, upon which a second type of circuit device 314 may be formed to provide the hybrid circuit configuration. The group III-N device layer 312 may accordingly have reduced stress, as discussed further above.

In the illustrated example, a second MST layer 325b (and optional cap layer 352b) is provided beneath one (or more) of the CMOS circuit devices 313 to provide mobility enhancement and/or dopant profile control features, as discussed further above. In some embodiments, the first MST layer 325a on the Si (111) handle wafer 301 may include carbon (MST-C), as also discussed above. Generally speaking, the handle wafer 301 may see relatively high temperature fluctuation, for which an MST-C film 325a may be particularly beneficial, as will be appreciated by those skilled in the art.

In one example implementation, the example CMOS/Group III integration may be used for microprocessor circuitry, which typically requires down conversion to achieve the appropriate lower operating voltages. The example embodiment may advantageously allow this step down to be performed locally where needed, which Applicant theorizes without wishing to be bound thereto may provide significant energy savings in microprocessor applications. This approach may also be applied to other types of electronic devices (e.g., RF transistors, power transistors, etc.), piezoelectric sensors, as well as optoelectronic devices (e.g., LEDs, micro-LEDs, lasers, optical detectors, etc.).

The example configuration advantageously allows for a bonded SOI wafer with different Si crystal orientations to monolithically integrate Si CMOS devices 313 and Group III-N (e.g., GaN) devices 314. Other approaches may utility cavity SOI, etc., as will be appreciated by those skilled in the art. Moreover, this approach combines the benefits of MST films for standalone III-N epi structures, with the ability to leverage these to improve heterointegration (i.e., reduced stress and/or the ability to grow thinner films).

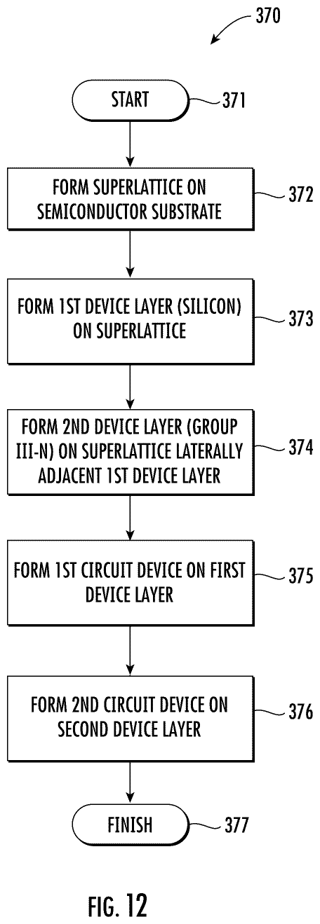

Turning now to the flow diagram 370 of FIG. 12, a method form making the hybrid semiconductor device 300 begins at Block 371 with forming the MST layer 325a (and optional cap layer 352a) on the handle wafer 301 (Block 372). The method further illustratively includes forming the first Si device layer 311 (e.g., a Si (100) layer) on the superlattice 352a, at Block 373, and forming the second device layer 312 on the superlattice laterally adjacent the first device layer, at Block 374. The second device layer 312 includes a Group III-N semiconductor (e.g., GaN, AlN, or a stack of Group III-N material layers as described above). The method also illustratively includes forming a first device 313 (e.g., CMOS) on the first device layer 311, and forming a second device 314 on the second device layer 312, at Blocks 375-376. The method of FIG. 12 illustratively concludes at Block 377.

In variations of the above-described embodiments, the MST films may be used for delivering non-semiconductor atoms (e.g., O, C, N) to the Si/AlN interface. More particularly, the MST film may be annealed at a relatively high temperature to cause atoms from the non-semiconductor monolayer(s) to relocate from their original position in the MST film in the Si substrate to the Si/AlN interface region. For example, annealing or heating may be performed prior to the AlN formation step, during the AlN formation step, or after the AlN formation step to cause non-semiconductor atoms from the MST layer to accumulate at the Si/AlN interface.

As discussed further in U.S. Pat. No. 10,109,479, which is also assigned to the present Assignee and is hereby incorporated herein in its entirety by reference, a buried insulating layer may be formed by depositing an MST layer, and subsequently annealing the structure. The annealing may be performed at approximately 750° C. or higher in an inert atmosphere (e.g., Ne, Ar, He, etc.), and more preferably in a range of about 800° C. to 1000° C. In some embodiments non-inert atmospheres (e.g., H₂) may also be used depending on the temperature range being used, for example. In the case of oxygen, for example, annealing causes the inserted non-semiconductor monolayers to decompose spinodally.

Applicant theorizes without wishing to be bound thereto that the oxygen atoms in an oxygen-MST layer (MST-O) will diffuse, and some of which will relocate to the Si/AlN interface. Depending on the embodiment, the original MST film structure may no longer be present after the annealing and/or further processing. It will be appreciated that the exemplary annealing times, temperatures, and environments, as well as the dosages and monolayer spacings, may be varied depending upon the particular application and materials being used. Generally speaking, the amount of non-semiconductor atoms at the Si/AlN interface may be in a range of 40-60% of the non-semiconductor atoms present in the originally-formed MST film, for example.

Applicant theorizes that the non-semiconductor atoms relocated to the Si/AlN interface provide similar stress relief benefits to the MST film being directly adjacent the interface, as discussed above. That is, both approaches may be used to position the non-semiconductor atoms directly adjacent or at the interface region, but in slightly different ways.

Other approaches for achieving this result may also potentially be used in different embodiments, such as a single non-semiconductor monolayer deposition on top of the Si substrate before formation of the AlN layer. In this regard, the amount of non-semiconductor atoms deposited may still be relatively low, such that semiconductor bonds can propagate across the non-semiconductor atoms to maintain crystalline growth, as discussed above with reference to the MST film formation. In yet another example approach, non-semiconductor atoms may instead be implanted at the Si/AlN interface to achieve stress reduction characteristics.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that other modifications and embodiments are intended to be included within the scope of the appended claims.

1. A semiconductor device comprising:
a semiconductor substrate;
a superlattice layer on the semiconductor substrate, the superlattice layer comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions; and
a piezoelectric layer on the superlattice layer and comprising a Group III-N semiconductor.

2. The semiconductor device of claim 1 further comprising at least one electrode adjacent the piezoelectric layer.

3. The semiconductor device of claim 2 wherein the at least one electrode is configured to induce an acoustic wave along a surface of the piezoelectric layer to define a surface acoustic wave (SAW) filter.

4. The semiconductor device of claim 2 wherein the at least one electrode is configured to induce an acoustic wave within the piezoelectric layer to define a bulk acoustic wave (BAW) filter.

5. The semiconductor device of claim 1 wherein the Group III-N semiconductor comprises at least one of AlN and ScN.

6. The semiconductor device of claim 1 wherein the semiconductor substrate comprises a single crystal silicon substrate having a (111) orientation with an off-cut of 0.5° or less.

7. The semiconductor device of claim 1 wherein the base semiconductor monolayers comprise silicon.

8. The semiconductor device of claim 1 wherein the at least one non-semiconductor monolayer comprises oxygen.

9. The semiconductor device of claim 1 wherein the at least one non-semiconductor monolayer comprises carbon.

10. A semiconductor device comprising:
a single crystal silicon substrate having a (111) orientation with an off-cut of 0.5°;
a superlattice layer on the single crystal silicon substrate, the superlattice layer comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions;
a piezoelectric layer on the superlattice layer and comprising comprises at least one of AlN and ScN; and
at least one electrode adjacent the piezoelectric layer.

11. The semiconductor device of claim 10 wherein the at least one electrode is configured to induce an acoustic wave along a surface of the piezoelectric layer to define a surface acoustic wave (SAW) filter.

12. The semiconductor device of claim 10 wherein the at least one electrode is configured to induce an acoustic wave within the piezoelectric layer to define a bulk acoustic wave (BAW) filter.

13. The semiconductor device of claim 10 wherein the base semiconductor monolayers comprise silicon.

14. The semiconductor device of claim 10 wherein the at least one non-semiconductor monolayer comprises oxygen.

15. The semiconductor device of claim 10 wherein the at least one non-semiconductor monolayer comprises carbon.

16. A semiconductor device comprising:
a semiconductor substrate;
a superlattice layer on the semiconductor substrate, the superlattice layer comprising a plurality of stacked groups of layers, each group of layers comprising a plurality of stacked base silicon monolayers defining a base silicon portion, and at least one oxygen monolayer constrained within a crystal lattice of adjacent base silicon portions; and
a piezoelectric layer on the superlattice layer and comprising a Group III-N semiconductor.

17. The semiconductor device of claim 16 further comprising at least one electrode adjacent the piezoelectric layer configured to induce an acoustic wave along a surface of the piezoelectric layer to define a surface acoustic wave (SAW) filter.

18. The semiconductor device of claim 16 further comprising at least one electrode adjacent the piezoelectric layer configured to induce an acoustic wave within the piezoelectric layer to define a bulk acoustic wave (BAW) filter.

19. The semiconductor device of claim 16 wherein the Group III-N semiconductor comprises at least one of AlN and ScN.

20. The semiconductor device of claim 16 wherein the semiconductor substrate comprises a single crystal silicon substrate having a (111) orientation.
